(19) United States
(12) Patent Application Publication
(10) Pub. No.: US 2020/0073245 A1
(43) Pub. Date: Mar. 5, 2020

(54) MASK AND CONTROL METHOD THEREOF

(71) Applicants: Beijing BOE Display Technology Co., Ltd., Beijing (CN); BOE TECHNOLOGY GROUP CO., LTD., Beijing (CN)

(72) Inventors: He Feng, Beijing (CN); Dong Wang, Beijing (CN)

(21) Appl. No.: 16/409,417

(22) Filed: May 10, 2019

(30) Foreign Application Priority Data
Aug. 30, 2018 (CN) 201811004828.9

(51) Int. Cl. G03F 7/20; G03F 7/00; G03F 7/09; G03F 7/16

(52) U.S. Cl. CPC G03F 7/2002; G03F 7/164; G03F 7/094; G03F 7/0007

(57) ABSTRACT

Arrangements of the present disclosure provide a mask and a control method thereof. The mask includes a first substrate and a second substrate disposed opposite to each other, and a functional layer between the first substrate and the second substrate. The functional layer is mainly formed of uniformly arranged functional particles. The functional particles are gathered and arranged under a vertical electric field. The functional particles are opaque. The mask further includes a first electrode disposed on the first substrate, and a second electrode disposed on the second substrate. The first electrode and the second electrode form a plurality of evenly distributed vertical voltage generation units.

### CROSS REFERENCE

This application is based upon and claims priority to Chinese Patent Application No. 201811004828.9, filed on Aug. 30, 2018, the entire contents thereof are incorporated herein by reference.

### TECHNICAL FIELD

The present disclosure relates to the technical field of masks, and in particular, to a mask and a control method thereof.

### BACKGROUND

In the production process of electronic products, it is often necessary to use a mask to form various patterned film layers, since one mask can only form one patterned film layer, such that for different electronic products or even in the production process of the same electronic product, it is often necessary to design different masks for different patterned film layers, resulting in an increase in production costs.

### SUMMARY

Arrangements of the present disclosure provide a mask and a control method thereof.

One aspect of an arrangement of the present disclosure provides a mask. The mask includes a first substrate and a second substrate disposed opposite to each other, and a functional layer between the first substrate and the second substrate. The functional layer is formed of functional particles evenly arranged. The functional particles are gathered and arranged under a vertical electric field, and the functional particles are opaque. The mask incudes a first electrode disposed on the first substrate, and a second electrode disposed on the second substrate. The first electrode and the second electrode form a plurality of evenly distributed vertical voltage generation units.

In some arrangements, the functional layer is a nanocrystalline magnetic layer mainly formed by uniformly arranged nanocrystalline magnetic particles.

In some arrangements, the first electrode includes at least one of: a group consisting of strip electrodes, block electrodes, and a combination of the strip electrodes and the block electrodes, disposed in a dispersed manner. The second electrode includes at least one of: one choice from a group consisting of a planar electrode, strip electrodes, block electrodes, and a combination of the strip electrodes and the block electrodes, disposed opposite to the first electrode.

In some arrangements, the first electrode and the second electrode are each composed of strip electrodes. The strip electrodes in the first electrode include a plurality of first strip electrodes disposed in parallel, at equal pitches and at least extending across an effective mask area of the mask. The strip electrodes in the first electrode include a plurality of second strip electrodes disposed in parallel, at equal pitches and at least extending across the effective mask area of the mask. The first strip electrodes and the second strip electrodes are perpendicular. The strip electrodes in the second electrode include a plurality of third strip electrodes disposed opposite to each of the first strip electrodes in a one to one correspondence and at least extending across the effective mask area of the mask. The strip electrodes in the second electrode include a plurality of fourth strip electrodes disposed opposite to each of the second strip electrodes in a one to one correspondence and at least extending across the effective mask area of the mask. A pair of one first strip electrode and one third strip electrode disposed opposite to each other form one vertical voltage generation unit. A pair of one second strip electrode and one fourth strip electrode disposed opposite to each other form one vertical voltage generation unit.

In some arrangements, the first electrode and the second electrode are each composed of block electrodes. The block electrodes in the first electrode include a plurality of first block electrodes evenly distributed. The block electrodes in the second electrode include a plurality of second block electrodes opposite to each of the first block electrodes in a one to one correspondence. A pair of one first block electrode and one second block electrode disposed opposite to each other form one vertical voltage generation unit.

In some arrangements, the second electrode is a planar electrode. The first electrode includes a plurality of block electrodes evenly distributed. The plurality of block electrodes and the planar electrode form the plurality of vertical voltage generation units evenly distributed.

In some arrangements, the second electrode is a planar electrode. The first electrode includes a plurality of fifth strip electrodes disposed in parallel, at equal pitches and at least extending across an effective mask area of the mask. The first electrode includes a plurality of sixth strip electrodes disposed in parallel, at equal pitches and at least extending across the effective mask area of the mask. The fifth strip electrodes and the sixth strip electrodes are perpendicular. The plurality of fifth strip electrodes and the plurality of sixth strip electrodes, together with the planar electrode, form the plurality of evenly distributed vertical voltage generation units.

In some arrangements, the planar electrode is a transparent electrode.

In some arrangements, the strip electrode and/or the block electrode is a metal electrode.

In some arrangements, the strip electrode has a width of 2 μm to 50 μm. A pitch of adjacent two strip electrodes along a width direction of the strip electrodes is 5 times to 10 times the width of the strip electrodes.

Another aspect of the present disclosure provides a method for controlling the mask described above. The method includes inputting a first voltage and a second voltage to the first electrode and the second electrode of the mask respectively to control part of the vertical voltage generation units to form vertical electric fields. As such, an area where the vertical electric fields are formed constitutes a light shielding area of the mask, and an area where no vertical electric field is formed constitutes a light transmitting area of the mask. T the first voltage is different from the second voltage.

### BRIEF DESCRIPTION OF THE DRAWINGS

In order to more clearly illustrate the arrangements of the present disclosure or the technical solutions in the related art, the drawings used in the arrangements or the description of the related art will be briefly described below. Apparently, the drawings in the following description are only some of the arrangements of the present disclosure, and other drawings can be obtained by those skilled in the art from theses drawings without paying any creative effort.

FIG. 1 is a schematic structural diagram of a mask according to an arrangement of the present disclosure;

FIG. 2 is a schematic cross-sectional view of FIG. 1 taken along the O-O′ position;

FIG. 3 is a schematic structural view of FIG. 2 in an operating state;

FIG. 4 is a schematic structural diagram of a middle electrode of a mask according to an arrangement of the present disclosure;

FIG. 5 is a schematic structural diagram of a middle electrode of another mask according to an arrangement of the present disclosure;

FIG. 6 is a schematic structural diagram of a middle electrode of another mask according to an arrangement of the present disclosure;

FIG. 7 is a schematic structural diagram of a middle electrode of another mask according to an arrangement of the present disclosure.

### DETAILED DESCRIPTION

The technical solutions in the arrangements of the present disclosure are clearly and completely described in the following with reference to the accompanying drawings in the arrangements of the present disclosure. Apparently, the described arrangements are only a part of the arrangements of the present disclosure, but not all arrangements. All other arrangements obtained by a person of ordinary skill in the art based on the arrangements of the present disclosure without paying creative efforts are within the scope of the present disclosure.

Unless otherwise defined, technical terms or scientific terms used in the arrangements of the present disclosure should be construed in the ordinary meaning of those of ordinary skill in the art. The terms “first”, “second” and similar terms used in the arrangements of the present disclosure do not denote any order, quantity, or importance, but are merely used to distinguish different components. The word “comprising” or “including” or the like means that the element or item preceding the word is intended to cover the element or item listed after the word and its equivalent, but without excluding other elements or items. Terms “connected to” or “connected with” and the like are not limited to physical or mechanical connections, but may include electrical connections, whether direct or indirect. “Upper”, “lower”, “left”, “right”, etc. are only used to indicate the relative positional relationship, and when the absolute position of the objects to be described is changed, the relative positional relationship may also change accordingly.

First of all, it should be understood by those skilled in the art that for a mask, an effective mask area is generally included, as well as an edge area located around the effective mask area. Of course, the effective mask area is the area in which the mask actually functions. In the effective mask area, a hollow pattern is generally provided, the hollow pattern constitutes a light transmission area of the mask, and a non-hollow area around the hollow pattern constitutes a light shielding area of the mask. In the actual exposure mask, the hollow pattern is utilized to form a mask pattern that is actually needed.

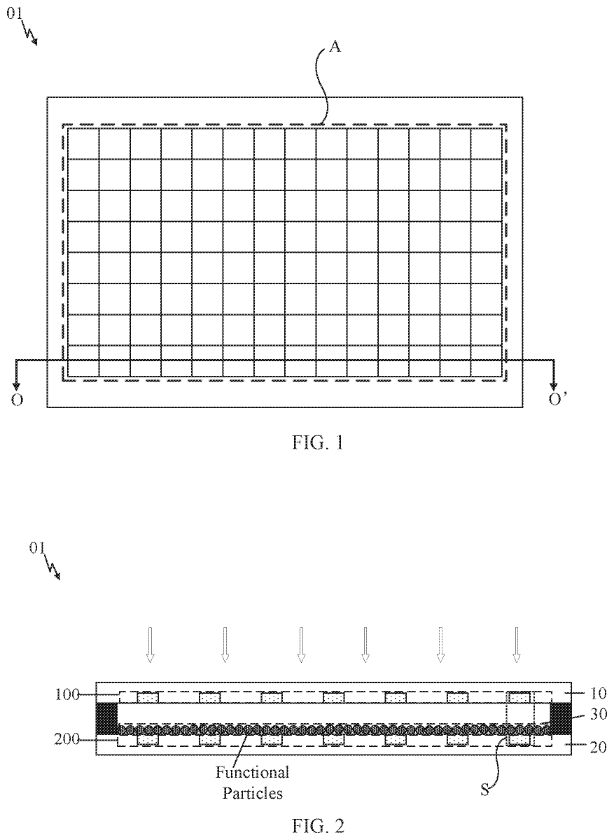

An arrangement of the present disclosure provides a mask, as shown in FIG. 1 and FIG. 2 (a cross-sectional view along the O-O′ position of FIG. 1). A mask 01 includes a first substrate 10 and a second substrate 20 disposed opposite to each other, and a functional layer 30 disposed between the first substrate 10 and the second substrate 20. The functional layer 30 is mainly formed by functional particles evenly arranged, and the functional particles are opaque. In practice, preferably, the functional layer 30 is mainly composed of nanocrystalline magnetic particles uniformly arranged to form a nanocrystalline magnetic layer. However, the present disclosure is not limited thereto, and the following arrangements are taken as an example to further illustrate the present disclosure.

On the basis of this, referring to FIG. 2, the first substrate 10 is provided with a first electrode 100, and the second substrate 20 is provided with a second electrode 200. The first electrode 100 and the second electrode 200 form a plurality of vertical voltage generation units evenly distributed. It can be understood that when an actual mask is required, the evenly distributed vertical voltage generation units S are at least evenly distributed in the effective mask area A.

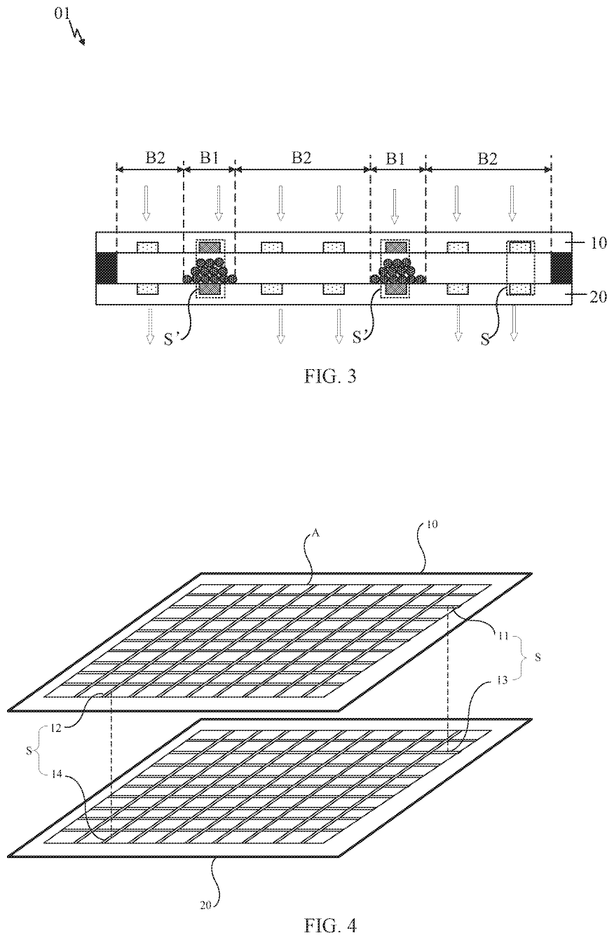

In this case, referring to FIG. 3 (a schematic diagram of the mask in FIG. 2 in an operating state), under action of a vertical electric field formed by a portion of the vertical voltage generation units S′ in the effective mask area A (in which grey electrodes represents being applied with an electric signal, to form a vertical electric field), the functional particles (nanocrystalline magnetic particles) of the functional layer 30 (nanocrystalline magnetic layer) that are located in an area where no vertical electric field is formed are moved to the area where a vertical electric field is formed, gathered and rearranged, such that the area where a vertical electric field is formed constitutes a light shielding area B1 of the mask 01, and the area where no vertical electric field is formed constitutes a light transmission area B2 of the mask.

Compared with the related art, different masks have to be designed for different mask requirements, in the mask of the present disclosure, according to actual needs, the functional particles in the functional layer between the first electrode and the second electrode can be controlled to be gathered and rearranged, such that part of the evenly distributed vertical voltage generation units formed by the first electrode and the second electrode form a vertical electric field, and under the action of the vertical electric field, opaque functional particles are moved from the area where no electric field is formed to the area where an electric field is formed, thus forming a light shielding area of the mask constituted by the area where an electric field is formed, and a light transmission area of the mask constituted by the area where no electric field is formed. That is, in the mask of the present disclosure, according to the actual mask pattern requirements, by controlling whether to generate an electric field by the vertical voltage generation units, it can realize defining and adjusting of the light transmission area and the light shielding area of the mask, and thus, the mask can meet various mask pattern requirements.

It should be noted that, in the present disclosure, a specific arrangement form of the first electrode 100 and the second electrode 200 forming a plurality of evenly distributed vertical voltage generation units S is not limited.

The first electrode 100 may include: strip electrodes disposed in a dispersed manner; or may include: block electrodes disposed in a dispersed manner; and may further include: strip electrodes and block electrodes disposed in a dispersed manner.

For the second electrode 200 described above, in some arrangements, the second electrode 200 may include: a planar electrode disposed opposite to all of the strip electrodes and the block electrodes in the first electrode 100. That is, the second electrode 200 includes an integral planar electrode opposite to the first electrode 100. The planar electrode and the strip electrodes and the block electrodes of the first electrode 100 respectively form the vertical voltage generation units S described above. By controlling whether to apply electric signals on the strip electrodes and the block electrodes and the magnitudes of the applied electric signals, it is possible to control whether to generate an electric field by the vertical voltage generation units S and the intensity of the electric field.

In some arrangements, the second electrode 200 may further include: strip electrodes disposed opposite to each of the strip electrodes of the first electrode 100 in a one to one correspondence. A pair of strip electrodes disposed opposite to each other form one vertical voltage generated unit S described above. By controlling whether to apply electric signals on the pair of strip electrodes opposite to each other and the magnitudes of the applied electric signals, it is possible to control whether to generate an electric field by the vertical voltage generation unit S and the intensity of the electric field.

In some arrangements, the second electrode 200 may further include: block electrodes disposed opposite to each of the block electrodes of the first electrode 100 in a one to one correspondence. A pair of block electrodes disposed opposite to each other form one vertical voltage generated unit S described above. By controlling whether to apply electric signals on the pair of block electrodes opposite to each other and the magnitudes of the applied electric signals, it is possible to control whether to generate an electric field by the vertical voltage generation unit S and the intensity of the electric field.

In some arrangements, the second electrode 200 may further include: a plurality of block electrodes disposed opposite to the strip electrodes in the first electrode 100, that is, each strip electrode is disposed opposite to a plurality of block electrodes. In this case, one strip electrode and a plurality of block electrodes form a plurality of vertical voltage generation units S, and each of the plurality of block electrodes can be separately controlled to control whether each vertical voltage generation unit S to generate a vertical electric field and the intensity of the electric field.

In some arrangements, the first electrode 100 includes both of strip electrodes and block electrodes, and the second electrode 200 may be a planar electrode, or may include both of strip electrodes and block electrodes. When the first electrode 100 and the second electrode 200 each includes both of strip electrodes and block electrodes, it is possible to dispose the strip electrodes opposite to the strip electrodes, the block electrodes opposite to the block electrodes, or it is also possible to dispose one strip electrode opposite to a plurality of block electrodes, which is not specifically limited in the present disclosure.

It should be noted here that the specific distinction between the strip electrodes, the block electrodes and the planar electrodes is actually based on the entire effective mask area A. For the planar electrode, it refers to an electrode at least covering the entire effective mask area A. For the strip electrodes and the block electrodes, it is not necessary to require the strip electrodes and the block electrodes to cover the entire effective mask area A, but at least require the strip electrodes and the block electrodes to be disposed in a dispersed manner in the effective mask area A, to ensure the plurality of vertical voltage generation units S evenly distributed in the effective mask area A.

On the basis of this, for the above-mentioned planar electrode, block electrodes, strip electrodes, it should be understood that for the planar electrode, since it covers the entire effective mask area A of the mask, in order to ensure light can be properly transmitted through the mask, the planar electrode is generally a transparent electrode, which may be a conductive film layer formed of a transparent conductive material, such as ITO (Indium tin oxide); or may be a conductive film formed of a metal material.

For the block electrodes or the strip electrodes, they may be transparent electrodes or non-transparent electrodes, which will not be limited in the present disclosure, as long as the electrode itself does not cause too much interference to the light transmitted through the mask, and does not affect proper masking.

However, it is generally considered that the electric resistance of the metal material is small. Preferably, the block electrodes and the strip electrodes are metal electrodes formed of metal material, such as copper, aluminum, etc. It is understood that the metal electrode itself has no light transmittance or, the light transmittance is very poor. Therefore, it is necessary to ensure that a sufficient gap is provided between adjacent metal electrodes to ensure the proper light transmittance of the mask.

For example, in some arrangements, when the strip electrodes are metal electrodes, the width of the strip electrode may be set to be 2 micrometers (μm) to 50 μm; and the pitch of adjacent strip electrodes in the width direction of the strip electrodes may be 5 to 10 times of the width of the metal electrodes, that is, 10 to 500 μm.

If the width of the strip electrode is less than 2 μm, the strip electrode may be too narrow. As such, the area where the electric field is formed may be too narrow, which is undesirable for controlling of the width of the light shielding area. When the width of the strip electrode is larger than 50 μm, the strip electrode is too wide, such that a light shielding area may be formed at the position of the electrode in the mask, which may adversely affects the mask, and is not desirable for some patterns that need to form a narrow light shielding area. Therefore, the preferred width of the strip electrode is actually 2 μm˜50 μm.

In addition, when the pitch between adjacent two strip electrodes in the width direction of the strip electrodes is less than 5 times the width of the metal electrode, that is, the density of the strip electrodes is too large, the light transmission effect of the mask is poor. When the pitch between adjacent two strip electrodes in the width direction of the strip electrodes is greater than 10 times the width of the metal electrode, that is, the density of the strip electrodes is too small, it may be undesirable for the pattern requiring a dense light shielding area. In practice, the pitch between adjacent two strip electrodes in the width direction of the strip electrodes is preferably 5 to 10 times the width of the metal electrode.

In other arrangements, when the block electrode is a metal electrode, the length and width of the block electrode may each be set to be less than 2 μm, and along the length and width directions of the block electrode, a pitch between adjacent two block electrodes is 5 to 10 times of the length or width of the block electrode. The specific reason is the same as the case where the strip electrode is a metal electrode, details of which will not be repeated herein.

In addition, it should be noted that, for the position between adjacent vertical voltage generation units S, in practice, by controlling the electric field intensity generated by the vertical voltage generation unit S, the degree of gathering of the nanocrystalline magnetic particles can be controlled to achieve control of the light shielding effect or the light transmission effect at the position between adjacent vertical voltage generation units S.

In addition, the above-described “the first electrode 100 and the second electrode 200 forming a plurality of evenly distributed vertical voltage generation units S” will be further described below with reference to specific arrangements.

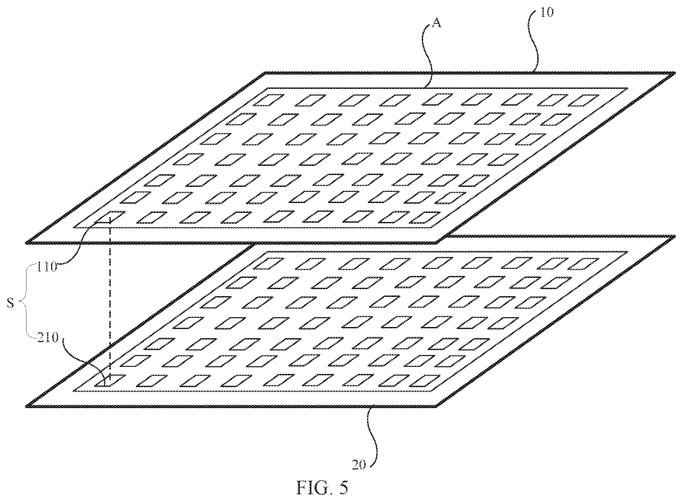

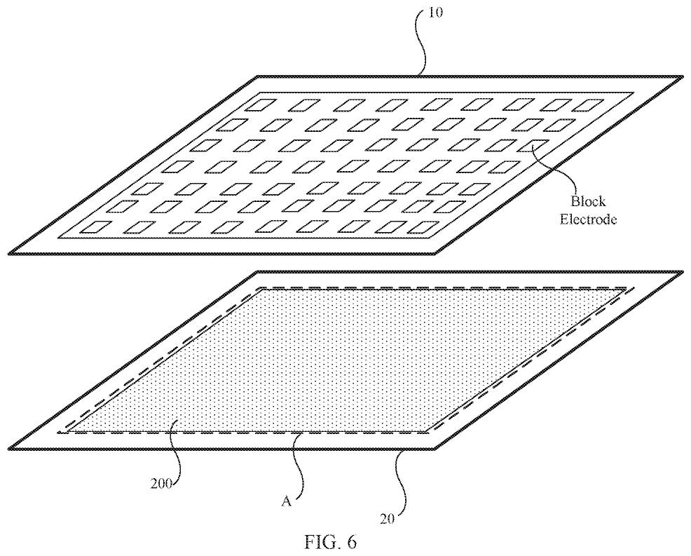

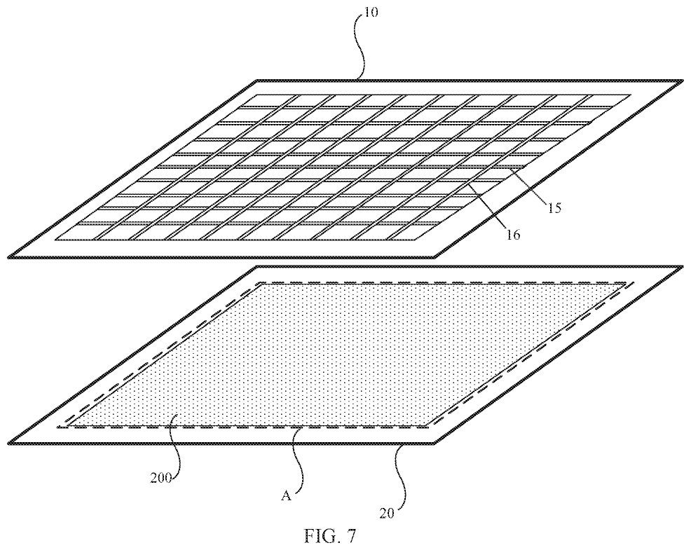

It should be noted that, in the present disclosure, one of the first substrate 10 and the second substrate 20 is used as the upper substrate, and the other is used as the lower substrate. In the drawings, for illustration convenience, only the first substrate 10 is used as the upper substrate, and the second substrate 20 is illustrated as a lower substrate as an example. In addition, FIG. 4, FIG. 5, FIG. 6, and FIG. 7 in the drawings of the present disclosure shown the two substrates respectively merely for the purpose of clearly explaining the arrangement of the electrodes, and the functional layers are not shown, which should not be considered unreasonable or unclear.

As shown in FIG. 4, the first electrode 100 on the first substrate 10 and the second electrode 200 on the second substrate 20 are each composed of strip electrodes.

The strip electrodes in the first electrode 100 includes: a plurality of first strip electrodes 11 disposed in parallel, at equal pitches and at least extending across the effective mask area A, and a plurality of second strip electrodes 12 disposed in parallel, at equal pitches and at least extending across the effective mask area A. The first strip electrodes 11 and the second strip electrodes 12 extend along different directions, and it is generally preferred that the first strip electrodes 11 and the second strip electrodes 12 are perpendicular.

The strip electrodes in the second electrode 200 includes: a plurality of third strip electrodes 13 disposed opposite to each of the first strip electrodes 11 in a one to one correspondence and at least extending across the effective mask area A, and a plurality of fourth strip electrodes 14 disposed opposite to each of the second strip electrodes 12 in a one to one correspondence and at least extending across the effective mask area A. The third strip electrodes 13 extend in a direction the same as the extending direction of the first strip electrodes 11, and the fourth strip electrodes 14 extend in a direction the same as the extending direction of the seconds strip electrodes 12.

It can be understood that the first strip electrodes 11 and the second strip electrodes 12 are separated by an insulating layer to ensure that the first strip electrodes 11 and the second strip electrodes 12 can properly transmit electrical signals. This applies similarly to the third strip electrodes 13 and the fourth strip electrodes 14.

In this case, referring to FIG. 4, a pair of one first strip electrode 11 and one third strip electrode disposed opposite to each other form one vertical voltage generation unit S; and a pair of one second strip electrode 12 and one fourth strip electrode 14 disposed opposite to each other form one vertical voltage generation unit S.

It should be noted that, in the present disclosure, “disposed opposite to each other” refers to describing the relative position of the associated objects, indicating that the two are disposed right opposite to each other; or, the orthographic projections of the two on the first substrate or the second substrate has at least overlapping area. It is generally preferred that one the orthographic projections of the two on the first substrate or the second substrate at least covers the other, or the orthographic projections coincide with each other.

For example, referring to FIG. 4, forming a color filter pattern with a matrix arranged with the above mask through an exposure mask using a negative photoresist will be described.

The extending direction of the first strip electrode 11 and the third strip electrode 13 is the extending direction of the gate line, that is, the row direction; the extending direction of the second strip electrode 12 and the fourth strip electrode 14 is the extending direction of the data line, that is, the column direction.

In the mask 01, the first strip electrodes 11 and the third strip electrodes 13 disposed at positions between adjacent rows of the color filter pattern may be respectively applied with different electrical signals, and simultaneously the second strip electrodes 12 and the fourth strip electrodes 14 disposed at positions between adjacent columns of the color filter pattern may be respectively applied with different electrical signals, such that vertical electric fields are formed in the mask at positions between adjacent rows of the color filter pattern and at positions between adjacent columns of the color filter pattern, and in turn, the nanocrystalline magnetic particles in the nanocrystalline magnetic layer which are located in the area where no vertical electric field is formed are moved to area where an electric field is formed, gathered and rearranged, thus forming light shielding areas B1 at positions between adjacent rows of the color filter pattern and at positions between adjacent columns of the color filter pattern, and forming light transmission areas B2 at positions of the color filter pattern.

In this way, the position of the photoresist layer (negative photoresist) located above the color filter layer corresponding to the color filter pattern can be exposed by an exposure process, and then the non-exposure area of the photoresist layer at the positions between adjacent rows of the color filter pattern and at positions between adjacent columns of the color filter pattern are dissolved with developer, thus completing the fabrication of the color filter pattern by subsequent etching, stripping, and the like.

It can be understood that, in practice, it is possible to control the intensity of the electric field by controlling the magnitude of the electric signals applied on the electrodes. In turn, the gathering degree of the nanocrystalline magnetic particles can be controlled, to meet requirements on color filter patterns from different products of different sizes and different specifications. For example, the intensity of the electric field can be increased by increasing the voltages applied to the electrodes, and thus the width of the formed light shielding area can be increased.

As shown in FIG. 5, the first electrode 100 on the first substrate 10 and the second electrode 200 on the second substrate 20 are each composed of block electrodes.

The first electrode 100 includes: a plurality of first block electrodes 110 evenly distributed (for example, may be arranged in a matrix); the second electrode 200 includes: a plurality of second block electrodes 210 opposite to each of the first block electrodes 110 in a one to one correspondence (it is understood that the second block electrodes 210 are distributed in the same manner as the first block electrodes 110), and a pair of one first block electrode 110 and one second block electrode 210 disposed opposite to each other form one vertical voltage generation unit S.

In this arrangement, it should be understood that the plurality of vertical voltage generation units S formed of the plurality of first block electrodes 110 and the plurality of second block electrodes 210 can be separately controlled, to form a mask 01 having light shielding areas and light transmission areas of any pattern in the effective mask area A.

In addition, for the first block electrodes 110 and the second block electrodes 210, a metal material may be used, or a transparent conductive material may be used. In order to avoid the block electrodes (including the first block electrodes 110 and the second block electrodes 210) itself affecting the light transmittance of the effective mask area A, causing that light cannot be properly transmitted through the position where the light transmittance area is actually required to be formed, and thus adversely affecting the proper masking, in practice, preferably, the first block electrodes 110 and the second block electrodes 210 are formed of a transparent conductive material such as ITO.

As shown in FIGS. 6 and 7, the second electrode 200 on the second substrate 20 is a planar electrode.

For the first electrode 100 located on the first substrate 10, in some arrangements, as shown in FIG. 6, the first electrode 100 includes: a plurality of block electrodes evenly distributed, and the plurality of block electrodes and the planar electrode as the second electrode 200 form the plurality of vertical voltage generation units S evenly distributed.

In some arrangements, as shown in FIG. 7, the first electrode 100 includes: a plurality of fifth strip electrodes 15 disposed in parallel, at equal pitches and at least extending across the effective mask area A, and a plurality of sixth strip electrodes 16 disposed in parallel, at equal pitches and at least extending across the effective mask area A. The fifth strip electrodes 15 and the sixth strip electrodes 16 extend along different directions, and it is generally preferred that the fifth strip electrodes 15 and the sixth strip electrodes 16 are perpendicular. In this case, the plurality of fifth strip electrodes 15 and the plurality of sixth strip electrodes 16, together with the planar electrode (the second electrode 200), form the plurality of vertical voltage generation units S evenly distributed.

It can be understood that the fifth strip electrodes 15 and the sixth strip electrodes 16 are separated by an insulating layer to ensure that the fifth strip electrode 15 and the sixth strip electrode 16 can properly transmit electrical signals.

The arrangement of the present disclosure further provides a method for controlling the mask 01 provided by the foregoing arrangements, and the control method is as following.

A first voltage and a second voltage are respectively input to the first electrode 100 and the second electrode 200 of the mask 01, to control part of the vertical voltage generation units S to form vertical electric fields, such that an area where a vertical electric field is formed constitutes a light shielding area of the mask 01, and an area where no vertical electric field is formed constitutes a light transmitting area of the mask 01. The first voltage is different from the second voltage.

Taking the first electrode 100 and the second electrode 200 as provided in the First Arrangement as an example, that is, when the first electrode 100 includes a plurality of first strip electrodes 11 disposed in parallel, in an evenly dispersed manner and extending across the effective mask area A along a first direction, and a plurality of second strip electrodes 12 disposed in parallel, in an evenly dispersed manner and extending across the effective mask area A along a second direction; and the second electrode 200 includes: a plurality of third strip electrodes 13 disposed opposite to each of the first strip electrodes 11 in a one to one correspondence, and a plurality of fourth strip electrodes 14 disposed opposite to each of the second strip electrodes 12 in a one to one correspondence, the control method will be further described with reference to a process of forming a black matrix pattern BM (located around the color filter pattern) on the color filter substrate through exposure mask by using a positive photoresist with the mask.

The control method may proceed as follows.

In the mask, different electric signals (a first voltage and a second voltage) are respectively applied to the first strip electrodes 11 and the third strip electrodes 13 at positions between adjacent rows of sub-pixel apertures.

At the same time, different electrical signals (a first voltage and a second voltage) are respectively applied to the second strip electrodes 12 and the fourth strip electrodes 14 at positions between adjacent columns of sub-pixel apertures.

In this way, in the mask, vertical electric fields are formed at positions between adjacent rows of sub-pixel apertures and positions between adjacent columns of sub-pixel apertures, such that the nanocrystalline magnetic particles in the nanocrystalline magnetic layer which are located in the area where no vertical electric field is formed are moved to area where an electric field is formed, gathered and rearranged, thus forming light shielding areas B1 at positions between adjacent rows of sub-pixel apertures and at positions between adjacent columns of sub-pixel apertures, and forming light transmission areas B2 at positions of the sub-pixel apertures.

The position of the photoresist layer (positive photoresist) located above the black matrix layer corresponding to the sub-pixel apertures can be exposed by an exposure process, and then the non-exposure area of the photoresist layer at the positions of the sub-pixel apertures are dissolved with developer, thus completing the fabrication of the color filter pattern by subsequent etching, stripping, and the like.

However, in practice, the actual electrical signals of the electrodes at different positions can be adjusted to meet the requirements on the black matrix pattern from different products of different sizes and different specifications.

Those skilled in the art can understand that all or part of the operations to implement the above method arrangements can be completed by using hardware related to the program instructions. The foregoing program can be stored in a computer readable storage medium. The program, when executed, performs the operations included in the above method arrangements. The foregoing storage medium includes: a medium that can store program codes, such as a ROM, a RAM, a magnetic disk, or an optical disk.

The above is only specific arrangements of the present disclosure, but the scope of the present disclosure is not limited thereto, and modifications or substitutions that any person skilled in the art can easily think of within the technical scope of the present disclosure should be covered by the scope of the present disclosure. Therefore, the scope of the present disclosure should be subject to the scope of the appended claims.

What is claimed is:

1. A mask comprising: a first substrate and a second substrate disposed opposite to each other, and a functional layer between the first substrate and the second substrate;
wherein the functional layer is formed of functional particles that are evenly arranged with one another, and the functional particles are gathered and arranged under a vertical electric field, and the functional particles are opaque;
a first electrode is disposed on the first substrate, and a second electrode is disposed on the second substrate; and the first electrode and the second electrode form a plurality of evenly distributed vertical voltage generation units.

2. The mask according to claim 1, wherein the functional layer is a nanocrystalline magnetic layer mainly formed by uniformly arranged nanocrystalline magnetic particles.

3. The mask according to claim 1, wherein
the first electrode comprises at least one of: a group consisting of strip electrodes, block electrodes, and a combination of the strip electrodes and the block electrodes, that are disposed in a dispersed manner; and
the second electrode comprises at least one of: a group consisting of a planar electrode, strip electrodes, block electrodes, and a combination of the strip electrodes and the block electrodes, that are disposed opposite to the first electrode.

4. The mask according to claim 3, wherein
the first electrode and the second electrode are each composed of strip electrodes;
the strip electrodes in the first electrode comprise: a plurality of first strip electrodes disposed in parallel, at equal pitches and at least extending across an effective mask area of the mask, and a plurality of second strip electrodes disposed in parallel, at equal pitches and at least extending across the effective mask area of the mask;
the plurality of first strip electrodes and the plurality of second strip electrodes are perpendicular;
the strip electrodes in the second electrode comprise: a plurality of third strip electrodes disposed opposite to each of the plurality of first strip electrodes in a one to one correspondence and at least extending across the effective mask area of the mask, and a plurality of fourth strip electrodes disposed opposite to each of the plurality of second strip electrodes in a one to one correspondence and at least extending across the effective mask area of the mask;
a pair of one first strip electrode and one third strip electrode disposed opposite to each other form one vertical voltage generation unit; and a pair of one second strip electrode and one fourth strip electrode disposed opposite to each other form one vertical voltage generation unit.

5. The mask according to claim 3, wherein
the first electrode and the second electrode are each composed of one or more of the block electrodes;
the block electrodes in the first electrode comprise: a plurality of first block electrodes evenly distributed;
the block electrodes in the second electrode comprise: a plurality of second block electrodes opposite to each of the first block electrodes in a one to one correspondence; and
a pair of one first block electrode and one second block electrode disposed opposite to each other form one vertical voltage generation unit.

6. The mask according to claim 3, wherein the second electrode is a planar electrode; and
the first electrode comprises: a plurality of block electrodes evenly distributed, and the plurality of block electrodes and the planar electrode form the plurality of vertical voltage generation units evenly distributed.

7. The mask according to claim 3, wherein the second electrode is a planar electrode; and
the first electrode comprises: a plurality of fifth strip electrodes disposed in parallel, at equal pitches and at least extending across an effective mask area of the mask, and a plurality of sixth strip electrodes disposed in parallel, at equal pitches and at least extending across the effective mask area of the mask;
the plurality of fifth strip electrodes and the plurality of sixth strip electrodes are perpendicular; and
the plurality of fifth strip electrodes and the plurality of sixth strip electrodes, together with the planar electrode, form the plurality of evenly distributed vertical voltage generation units.

8. The mask according to claim 3, wherein the planar electrode is a transparent electrode.

9. The mask according to claim 3, wherein the strip electrode and/or the block electrode is a metal electrode.

10. The mask according to claim 9, wherein
the strip electrode has a width of 2 μm to 50 μm; and
a pitch of adjacent two strip electrodes along a width direction of the strip electrodes is 5 times to 10 times the width of the strip electrodes.

11. A method for controlling the mask according to claim 1, comprising:
inputting a first voltage and a second voltage to the first electrode and the second electrode of the mask respectively to control part of the vertical voltage generation units to form vertical electric fields, such that an area where the vertical electric fields are formed constitutes a light shielding area of the mask, and an area where no vertical electric field is formed constitutes a light transmitting area of the mask, wherein the first voltage is different from the second voltage.

12. A mask manufacturing method, comprising:
providing a first substrate and a second substrate disposed opposite to each other, and a functional layer between the first substrate and the second substrate, wherein the functional layer is formed of functional particles evenly arranged, and the functional particles are gathered and arranged under a vertical electric field, and the functional particles are opaque;
disposing a first electrode on the first substrate and disposing a second electrode on the second substrate, so that the first electrode and the second electrode form a plurality of evenly distributed vertical voltage generation units.

13. The method according to claim 12, wherein the functional layer is a nanocrystalline magnetic layer mainly formed by uniformly arranged nanocrystalline magnetic particles.

14. The method according to claim 12, wherein
disposing a first electrode on the first substrate comprises: disposing one choice from a group consisting of strip electrodes, block electrodes, and a combination of the strip electrodes and the block electrodes, in a dispersed manner;
disposing a second electrode on the second substrate comprises: disposing one choice from a group consisting of a planar electrode, strip electrodes, block electrodes, and a combination of the strip electrodes and the block electrodes, opposite to the first electrode.

15. The method according to claim 14, wherein
the first electrode and the second electrode are each composed of one or more of the strip electrodes;
disposing a first electrode on the first substrate comprise: disposing a plurality of first strip electrodes in parallel, at equal pitches and at least extending across an effective mask area of the mask, and disposing a plurality of second strip electrodes in parallel, at equal pitches and at least extending across the effective mask area of the mask; wherein the first strip electrodes and the second strip electrodes are perpendicular;
disposing a second electrode on the second substrate comprise: disposing a plurality of third strip electrodes opposite to each of the first strip electrodes in a one to one correspondence and at least extending across the effective mask area of the mask, and disposing a plurality of fourth strip electrodes opposite to each of the second strip electrodes in a one to one correspondence and at least extending across the effective mask area of the mask; and
wherein a pair of one first strip electrode and one third strip electrode disposed opposite to each other form one vertical voltage generation unit; and a pair of one second strip electrode and one fourth strip electrode disposed opposite to each other form one vertical voltage generation unit.

16. The method according to claim 14, wherein
the first electrode and the second electrode are each composed of block electrodes;
disposing a first electrode on the first substrate comprises:
disposing a plurality of first block electrodes evenly distributed; and
disposing a second electrode on the second substrate comprises: disposing a plurality of second block electrodes opposite to each of the first block electrodes in a one to one correspondence; and disposing a pair of one first block electrode and one second block electrode opposite to each other form one vertical voltage generation unit.

17. The method according to claim 14, wherein the second electrode is a planar electrode; and
disposing a first electrode on the first substrate comprises: disposing a plurality of block electrodes evenly distributed, wherein the plurality of block electrodes and the planar electrode form the plurality of vertical voltage generation units evenly distributed.

18. The method according to claim 14, wherein the second electrode is a planar electrode; and
disposing a first electrode on the first substrate comprises: disposing a plurality of fifth strip electrodes in parallel, at equal pitches and at least extending across an effective mask area of the mask, and disposing a plurality of sixth strip electrodes in parallel, at equal pitches and at least extending across the effective mask area of the mask, wherein the fifth strip electrodes and the sixth strip electrodes are perpendicular; and the plurality of fifth strip electrodes and the plurality of sixth strip electrodes, together with the planar electrode, form the plurality of evenly distributed vertical voltage generation units.

19. The method according to claim 14, wherein the planar electrode is a transparent electrode.

20. The method according to claim 19, wherein
the strip electrode has a width of 2 micrometers (μm) to 50 μm; and
a pitch of adjacent two strip electrodes along a width direction of the strip electrodes is 5 times to 10 times the width of the strip electrodes.
